(19) United States
(12) Patent Application Publication
(10) Pub. No.: US 2024/0106199 A1
(43) Pub. Date: Mar. 28, 2024

(54) SURFACE-EMITTING LASER WITH MULTILAYER THERMALLY CONDUCTIVE MIRROR

(71) Applicant: Taiwan-Asia Semiconductor Corporation, Hsinchu City (TW)

(72) Inventor: Chuan-Wei CHEN, Hsinchu City (TW)

(21) Appl. No.: 18/465,452

(22) Filed: Sep. 12, 2023

(30) Foreign Application Priority Data
Sep. 15, 2022 (TW) 111134906

(51) Int. Cl. H01S 5/183

(52) U.S. Cl. CPC H01S 5/18375; H01S 5/02469

(57) ABSTRACT

The surface-emitting laser with a multilayer thermally conductive mirror includes a light-emitting layer, an oxide layer, first and second mirror layers, and first and second contact layers. The light-emitting layer generates light with a wavelength of A. The oxide layer has an oxide aperture to limit the current flowing into the light-emitting layer. The first mirror layer includes a first high thermally conductive layer and a first low thermally conductive layer. The second mirror layer includes a second high thermally conductive layer and a second low thermally conductive layer. The first contact layer is disposed of on one side of the first mirror layer by the first low thermally conductive layer. The second contact layer is disposed on one side of the second mirror layer by the second high thermally conductive layer. The overall light emission and heat dissipation efficiency can be improved.

This application claims priority to Taiwan Patent Application No. 111134906 filed on Sep. 15, 2022, which is hereby incorporated by reference in its entirety.

### CROSS-REFERENCES TO RELATED APPLICATIONS

Not applicable.

### BACKGROUND OF THE INVENTION

### Field of the Invention

The present invention relates to the technical field of surface-emitting lasers, particularly a surface-emitting laser with a multilayer thermally conductive mirror.

### Descriptions of the Related Art

Traditionally, a surface-emitting laser (or named a vertical cavity surface-emitting laser, VCSEL) has a light emitting area with a diameter of several micrometers. The light emitting area will produce heat sources in the zone of the light emitting area, which has a high current density for performing electrical energy gap conversion to produce light sources, and these heat sources are mainly dissipated through stacks of mirror layers located above or below the light emitting area. For example, in the red wavelength mirrors, a material of Al_{(0.4-0.6)}GaAs or Al_{>0.9}XGaAs is used for the stacks of layers, and each layer has a thickness of λ/4; however, since the heat dissipation coefficient of Al_{(0.4-0.6)}GaAs is less than a quarter of that of Al_{>0.9}GaAs, the heat sources in the light emitting area cannot be effectively conducted to achieve heat dissipation.

In order to solve the deficiencies mentioned above, the existing technologies have proposed using the high heat dissipation nλ/4 as the material of the mirror; however, the existing technologies still have the disadvantage of not being able to dissipate heat effectively.

Given this, the present invention provides a surface-emitting laser with a multilayer thermally conductive mirror to solve the deficiencies of the conventional technology.

### SUMMARY OF THE INVENTION

The objective of the present invention is to provide a surface-emitting laser with a multilayer thermally conductive mirror, which provides a reflective structure with high heat dissipation efficiency to achieve a high heat dissipation effect.

The objective of the present invention is to provide the surface-emitting laser with the multilayer thermally conductive mirror as aforementioned, which includes a first mirror layer with a first high thermally conductive layer and a first low thermally conductive layer and a second mirror layer with a second high thermally conductive layer and a second low thermally conductive layer. The total thickness of the high thermally conductive layer and low thermally conductive layer is λ/4 or n×λ/4.

The objective of the present invention is to provide the surface-emitting laser with the multilayer thermally conductive mirror as aforementioned. The surface-emitting laser with the multilayer thermally conductive mirror includes a multilayer of first mirrors and/or a multilayer of second mirrors to increase the thickness of the high thermally conductive layer.

The objective of the present invention is to provide the surface-emitting laser with the multilayer thermal conductivity mirror as aforementioned, which has the adjusted composition percentage of the aluminum metal component in the high thermally conductive layer and/or in the material of the high thermally conductive layer.

The objective of the present invention is to provide the surface-emitting laser with the multilayer thermally conductive mirror as aforementioned, which has the adjusted thickness and/or the adjusted composition percentage of the aluminum metal component of the first high thermally conductive layer so that the current limit of the first high thermally conductive layer will not be affected by the oxidation process.

The objective of the present invention is to provide the surface-emitting laser with the multilayer thermally conductive mirror as aforementioned, which has the adjusted thickness and/or the adjusted composition percentage of the aluminum metal component of the second high thermally conductive layer (e.g., in the second mirror layer within the depth of the Mesa process etching range) so that the current limit of the second high thermally conductive layer will not be affected by the oxidation process.

The objective of the present invention is to provide the surface-emitting laser with the multilayer thermally conductive mirror as aforementioned, which provides a high thermally conductive layer with a thickness of

$$\\ ( n \times \frac{λ}{4} ) + Δ λ$$

and a low thermally conductive layer with a thickness of

$$\\ ( \frac{λ}{4} ) - Δ λ .$$

The objective of the present invention is to provide the surface-emitting laser with the multilayer thermally conductive mirror as aforementioned, which is applied to oxidation-type and nonoxidation-type surface-emitting lasers.

In order to achieve the above objectives or other objectives, the present invention provides a surface-emitting laser with the multilayer thermally conductive, which includes a light-emitting layer, an oxide layer, a first mirror layer, a second mirror layer, a first contact layer and a second contact layer. The light-emitting layer is capable of generating light having a wavelength of λ. The oxide layer is arranged on one side of the light-emitting layer. The oxide layer has an oxide aperture, and a material of the oxide layer is AlₓGaAs. The first mirror layer includes a first high thermally conductive layer and a first low thermally conductive layer. The first low thermally conductive layer is arranged between the first high thermally conductive layer and the oxide layer. The first high thermally conductive layer has a thickness of

$$\\ ( n \times \frac{λ}{4} ) + Δ λ ,$$

and the first low thermally conductive layer has a thickness of

$$\\ ( \frac{λ}{4} ) - Δ λ ,$$

wherein n is a positive integer, a material of the first high thermally conductive layer is AlₓGaAs, and a material of the first low thermally conductive layer is AlₓGaAs. The second mirror layer includes a second high thermally conductive layer and a second low thermally conductive layer. The second high thermally conductive layer is arranged between the second low thermally conductive layer and the light-emitting layer. The second high thermally conductive layer has a thickness of

$$\\ ( n \times \frac{λ}{4} ) + Δ λ ,$$

and the second low thermally conductive layer has a thickness of

$$( \frac{λ}{4} ) - Δ λ ,$$

wherein n is a positive integer, a material of the second high thermally conductive layer is AlₓGaAs, and a material of the second low thermally conductive layer is AlₓGaAs. The first contact layer has a first electrode and the first low thermally conductive layer, and the first contact layer is disposed on one side of the first mirror layer by the first low thermally conductive layer. The second contact layer has a second electrode and the second high thermally conductive layer, and the second contact layer is disposed on one side of the second mirror layer by the second high thermally conductive layer.

In an embodiment, aluminum content in the oxide layer of AlₓGaAs has x greater than or equal to 0.98.

In an embodiment, aluminum content in the first high thermally conductive layer of AlₓGaAs has x less than or equal to 0.98 and aluminum content in the first low thermally conductive layer of AlₓGaAs has x not greater than 0.6.

In an embodiment, aluminum content in the second high thermally conductive layer of AlₓGaAs has x less than or equal to 0.98 and aluminum content in the second low thermally conductive layer of AlₓGaAs has x not greater than 0.6.

In an embodiment, the oxidation rate of at least one of the first high thermally conductive layer and the second high thermally conductive layer is less than or equal to that of the oxidation layer.

In an embodiment, at least one of the first mirror layer and the second mirror layer consists of a single layer or a plurality of layers.

In an embodiment, when the first has a multilayer structure, the first high thermally conductive layer is in contact with and adjacent to a first low thermally conductive layer of another first mirror layer.

In an embodiment, when the second mirror layer has a multilayer structure, the second low thermally conductive layer is in contact with and adjacent to a second high thermally conductive layer of another second mirror layer.

In an embodiment, the surface-emitting laser with the multilayer thermally conductive mirror further includes a fourth reflective layer contacting the second contact layer. The fourth reflective layer includes a fourth high thermally conductive layer and a fourth low thermally conductive layer. The fourth high thermally conductive layer is arranged between the fourth low thermally conductive layer and the second low thermally conductive layer. The fourth high thermally conductive layer has a thickness of

$$( n \times \frac{λ}{4} ) + Δ λ ,$$

and the fourth low thermally conductive layer has a thickness of

$$( \frac{λ}{4} ) - Δ λ ,$$

where n is a positive integer, and a material of the fourth high thermally conductive layer is AlₓGaAs and a material of the fourth low thermally conductive layer is AlₓGaAs. In addition, aluminum content in the fourth high thermally conductive layer of AlₓGaAs has x greater than or equal to 0.98, and aluminum content in the fourth low thermally conductive layer of AlₓGaAs has x less than or equal to 0.6.

In an embodiment, the total thickness of the first high thermally conductive layer and the first low thermally conductive layer is n×λ/4, where n is a positive integer; and the total thickness of the second high thermally conductive layer and the second low thermally conductive layer is n×λ/4, where n is a positive integer.

### BRIEF DESCRIPTION OF THE DRAWINGS

FIG. 1 is a cross-sectional view of a surface-emitting laser with a multilayer thermally conductive mirror according to a first embodiment of the present invention.

FIG. 2 is a cross-sectional view of a surface-emitting laser with a multilayer thermally conductive mirror according to a second embodiment of the present invention.

### DETAILED DESCRIPTION OF THE PREFERRED EMBODIMENT

Since the various aspects and embodiments are merely illustrative and not restrictive, after reading this specification, there may also be other aspects and embodiments without departing from the scope of the present invention to a person having ordinary skill in the art. The features and advantages of these embodiments and scope of the patent application will be better appreciated from the following detailed description.

Herein, “a” or “an” is used to describe one or more elements and components described herein. Such a descriptive term is merely for the convenience of illustration and to provide a general sense of the scope of the present invention. Therefore, unless expressly stated otherwise, the term “a” or “an” is to be understood to include one or at least one, and the singular form also includes the plural form.

As used herein, the term “comprise” “include,” “have” or any other similar term is not intended to exclude additional, unrecited elements. For example, a device or structure comprising/including/having a plurality of elements is not limited to the elements listed herein but may comprise/include/have other elements not explicitly listed but generally inherent to the element or structure.

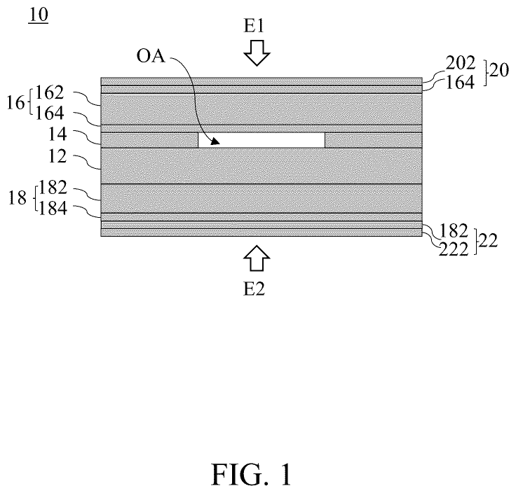

Please refer to FIG. 1, which is a cross-sectional view of the surface-emitting laser with the multilayer thermally conductive mirror according to the first embodiment of the present invention. In FIG. 1, the surface-emitting laser with the multilayer thermally conductive mirror 10 includes a light-emitting layer 12, an oxide layer 14, a first mirror layer 16, a second mirror layer 18, a first contact layer 20 and a second contact layer 22. In this embodiment, an upper layer and a lower layer are taken as an example for illustration. In other embodiments, there may be multiple layers.

The light-emitting layer 12 is capable of generating light, and the light has a wavelength of λ; for example, the wavelength ranges from 620 nm to 660 nm.

The oxide layer 14 is disposed on one side of the light-emitting layer 12, and here, the side is the +Y direction of the drawing. In addition, the oxide layer 14 forms an oxidation aperture OA for limiting the current flowing into the light-emitting layer 12, and the material of the oxide layer 14 is AlₓGaAs. In this embodiment, aluminum content in the oxide layer 14 of AlₓGaAs has x greater than or equal to 0.98, and in other embodiments, it may be other composition percentages.

The first mirror layer 16 includes a first high thermally conductive layer 162 and a first low thermally conductive layer 164. The first low thermally conductive layer 164 is arranged between the first high thermally conductive layer 162 and the oxide layer 14, i.e., from the −Y direction to the +Y direction of the drawing, the oxide layer 14, the first low thermally conductive layer 164 and the first high thermally conductive layer 162 are sequentially arranged. The thickness of the first high thermally conductive layer 162 is

$$( n \times \frac{λ}{4} ) + Δ λ$$

and the thickness of the first low thermally conductive layer 164 is

$$( \frac{λ}{4} ) - Δ λ ,$$

wherein n is a positive integer. Moreover, the material of the first high thermally conductive layer 162 is AlₓGaAs and the material of the first low thermally conductive layer 164 is AlₓGaAs. Further, the aluminum content in the first high thermally conductive layer 162 of AlₓGaAs has x less than or equal to 0.98, and the aluminum content in the first low thermally conductive layer 184 of AlₓGaAs has x less than or equal to 0.6.

In another embodiment, the oxidation rate of the first high thermally conductive layer 162 is less than or equal to the oxidation rate of the oxide layer 14. The oxidation rate is related to the change of the oxidation process, which is related to the aluminum content and thickness of the first high thermally conductive layer 162.

The second mirror layer 18 includes a second high thermally conductive layer 182 and a second low thermally conductive layer 184. The second high thermally conductive layer 182 is arranged between the second low thermally conductive layer 184 and the light-emitting layer 12, i.e., from the +Y direction to the −Y direction of the drawing, the oxide layer 12, the second high thermally conductive layer 182 and the second low thermally conductive layer 184 are sequentially arranged. The thickness of the second high thermally conductive layer 182 is

$$( n \times \frac{λ}{4} ) + Δ λ$$

and the thickness of the second low thermally conductive layer 184 is

$$( \frac{λ}{4} ) - Δ λ ,$$

wherein n is a positive integer. Moreover, the material of the second high thermally conductive layer 182 is AlₓGaAs, and the material of the second low thermally conductive layer 184 is AlₓGaAs. Further, the aluminum content in the second high thermally conductive layer 182 of AlₓGaAs has x less than or equal to 0.98, and the aluminum content in the second low thermally conductive layer 184 of AlₓGaAs has x less than or equal to 0.6.

In the above embodiment, the total thickness of the first high thermally conductive layer 162 and the first low thermally conductive layer 164 is n×λ/4, wherein n is a positive integer. Furthermore, the total thickness of the second high thermally conductive layer 182 and the second low thermally conductive layer 184 is n×λ/4, wherein n is a positive integer.

In another embodiment, the oxidation rate of the second high thermally conductive layer 182 is less than or equal to the oxidation rate of the oxide layer 14. The oxidation rate is related to the change of the oxidation process, which is related to the aluminum content and thickness of the second high thermally conductive layer 182.

The first contact layer 20 has a first electrode 202 and a first low thermally conductive layer 164. The first contact layer 20 is disposed on one side of the first mirror layer 16 by the first low thermally conductive layer 164, i.e., located in the +Y direction, for receiving the first electrical signal E1, e.g., the first electrical signal E1 is a positive voltage.

The second contact layer 22 has a second electrode 222 and a second high thermally conductive layer 182. The second contact layer 22 is disposed on one side of the second mirror layer 18 by the second high thermally conductive layer 182, i.e., located in the −Y direction, for receiving the second electrical signal E2, e.g., the second electrical signal E2 is a negative voltage.

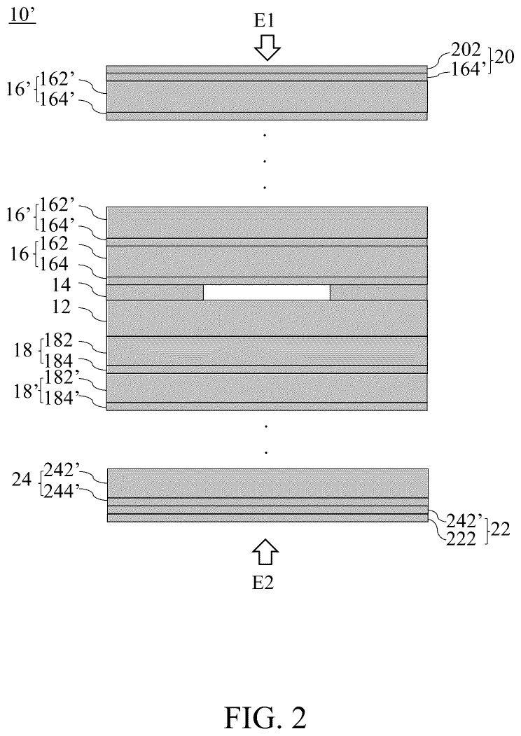

Referring to FIG. 2, which is a cross-sectional view of a surface-emitting laser with a multilayer thermally conductive mirror according to a second embodiment of the present invention. In FIG. 2, in addition to the light-emitting layer 12, the oxide layer 14, the first mirror layer 16, the second mirror layer 18, the first contact layer 20 and the second contact layer 22 in the first embodiment, the surface-emitting laser with the multilayer thermally conductive mirror 10′ further includes a fourth reflective layer 24.

The light-emitting layer 12, the oxide layer 14, the first mirror layer 16, the second mirror layer 18, the first contact layer 20 and the second contact layer 22 are as mentioned above and will not be further described here.

In addition, in this embodiment, the first mirror layer 16 and the second mirror layer 18 are described by taking multilayers as an example. Furthermore, the first mirror layer 16 is provided in such a manner that the first high thermally conductive layer 162 in contact with and adjacent to the first low thermally conductive layer 164′ of another first mirror layer 16′; when the second mirror layer 18 has a multilayer structure, the second low thermally conductive layer 184 is provided in such a manner as to be in contact with and adjacent to the second high thermally conductive layer 182′ of another second mirror layer 18′.

The fourth reflective layer 24 is in contact with the second contact layer 22, and the fourth reflective layer 24 has a fourth high thermally conductive layer 242′ and a fourth low thermally conductive layer 244′, where the second contact layer 22 contacts the fourth low thermally conductive layer 244′. The fourth high thermally conductive layer 242′ is arranged between the fourth low thermally conductive layer 244′ and the second low thermally conductive layer 184′. The thickness of the fourth high thermally conductive layer 242′ is

$$( n \times \frac{λ}{4} ) + Δ λ$$

and the thickness of the fourth low thermally conductive layer 244′ is

$$( \frac{λ}{4} ) - Δ λ ,$$

wherein n is a positive integer. The material of the fourth high thermally conductive layer 242′ is AlₓGaAs, and the material of the fourth low thermally conductive layer 244′ is AlₓGaAs. In addition, the aluminum content in the fourth high thermally conductive layer 242′ of AlₓGaAs has x not less than 0.98, and the aluminum content in the fourth low thermally conductive layer 244′ of AlₓGaAs has x not greater than 0.6.

The foregoing detailed description is illustrative in nature only and is not intended to limit the embodiments of the claimed subject matters or the applications or uses of such embodiments. Furthermore, while at least one exemplary embodiment has been presented in the foregoing detailed description, it should be appreciated that a wide variety of modifications to the present invention are possible. It should also be appreciated that the embodiments described herein are not intended to limit the scope, use, or configuration of the claimed subject matters in any way. Instead, the foregoing detailed description is intended to provide a person having ordinary skill in the art with a convenient guide for implementing one or more of the described embodiments. Moreover, various modifications may be made in the function and arrangement of the elements without departing from the scope defined by the claims, including known equivalents and any equivalents that may be anticipated at the time of filing this patent application.

What is claimed is:

1. A surface-emitting laser with a multilayer thermally conductive mirror, including:
a light-emitting layer for generating light having a wavelength of λ;
an oxide layer disposed on one side of the light-emitting layer, the oxide layer having an oxide aperture, a material of the oxide aperture being AlₓGaAs;
a first mirror layer having a first high thermally conductive layer and a first low thermally conductive layer arranged between the first high thermally conductive layer and the oxide layer, wherein the first high thermally conductive layer has a thickness of
$$( n \times \frac{λ}{4} ) + Δ λ ,$$
and the first low thermally conductive layer has a thickness of
$$( \frac{λ}{4} ) - Δ λ ,$$
wherein n is a positive integer, a material of the first high thermally conductive layer is AlₓGaAs, and a material of the first low thermally conductive layer is AlₓGaAs;
a second mirror layer having a second high thermally conductive layer and a second low thermally conductive layer wherein the second high thermally conductive layer is arranged between the second low thermally conductive layer and the light-emitting layer, wherein the second high thermally conductive layer has a thickness of
$$( n \times \frac{λ}{4} ) + Δ λ ,$$
and the second low thermally conductive layer has a thickness of
$$( \frac{λ}{4} ) - Δ λ ,$$
wherein n is a positive integer, a material of the second high thermally conductive layer is AlₓGaAs, and a material of the second low thermally conductive layer is AlₓGaAs;
a first contact layer having a first electrode and the first low thermally conductive layer, the first contact layer being disposed on one side of the first mirror layer by the first low thermally conductive layer; and
a second contact layer having a second electrode and the second high thermally conductive layer, the second contact layer being disposed on one side of the second mirror layer by the second high thermally conductive layer.

2. The surface-emitting laser with the multilayer thermally conductive mirror of claim 1, wherein aluminum content in the oxide layer of AlₓGaAs has x not less than 0.98.

3. The surface-emitting laser with the multilayer thermally conductive mirror of claim 1, wherein aluminum content in the first high thermally conductive layer of AlₓGaAs has x not greater than 0.98 and aluminum content in the first low thermally conductive layer of AlₓGaAs has x not greater than 0.6.

4. The surface-emitting laser with the multilayer thermally conductive mirror of claim 1, wherein aluminum content in the second high thermally conductive layer of AlₓGaAs has x not greater than 0.98, and aluminum content in the second low thermally conductive layer of AlₓGaAs has x not greater than 0.6.

5. The surface-emitting laser with the multilayer thermally conductive mirror of claim 1, wherein an oxidation rate of at least one of the first high thermally conductive layer and the second highly thermally conductive layer is not greater than an oxidation rate of the oxide layer.

6. The surface-emitting laser with the multilayer thermally conductive mirror of claim 1, wherein at least one of the first mirror layer and the second mirror layer consists of a single layer or a plurality of layers.

7. The surface-emitting laser with the multilayer thermally conductive mirror of claim 6, wherein when the first mirror layer has a multilayer structure, the first high thermally conductive layer is in contact with and adjacent to a first low thermally conductive layer of another first mirror layer.

8. The surface-emitting laser with the multilayer thermally conductive mirror of claim 6, wherein when the second mirror layer has a multilayer structure, the second low thermally conductive layer is in contact with and adjacent to a second high thermally conductive layer of another second mirror layer.

9. The surface-emitting laser with the multilayer thermally conductive mirror of claim 1, further comprising a fourth reflective layer in contact with the second contact layer, wherein the fourth reflective layer has a fourth high thermally conductive layer and a fourth low thermally conductive layer, the fourth high thermally conductive layer is arranged between the fourth low thermally conductive layer and the second low thermally conductive layer, wherein the fourth high thermally conductive layer has a thickness of
$$( n \times \frac{λ}{4} ) + Δ λ$$
and the fourth low thermally conductive layer has a thickness of
$$( \frac{λ}{4} ) - Δ λ ,$$
wherein n is a positive integer, and a material of the fourth high thermally conductive layer is AlₓGaAs and a material of the fourth low thermally conductive layer is AlₓGaAs, wherein aluminum content in the fourth high thermally conductive layer of AlₓGaAs has x not less than 0.98, and aluminum content in the fourth low thermally conductive layer of AlₓGaAs has x not greater than 0.6.

10. The surface-emitting laser with the multilayer thermally conductive mirror of claim 1, wherein a total thickness of the first high thermally conductive layer and the first low thermally conductive layer is n×λ/4, and a total thickness of the second high thermally conductive layer and the second low thermally conductive layer is n×λ/4, wherein n is a positive integer.
